(19) United States
(12) Patent Application Publication
(10) Pub. No.: US 2020/0400710 A1
(43) Pub. Date: Dec. 24, 2020

(54) CHARGE OUTPUT ELEMENT AND PIEZOELECTRIC ACCELERATION SENSOR

(71) Applicant: FATRI (Xiamen) Technologies Co., Ltd., Xiamen City (CN)

(72) Inventors: Yongzhong NIE, Xiamen City (CN); Chuan NIE, Xiamen City (CN)

(73) Assignee: FATRI (Xiamen) Technologies Co., Ltd., Xiamen City (CN)

(21) Appl. No.: 16/562,928

(22) Filed: Sep. 6, 2019

(30) Foreign Application Priority Data
Jun. 21, 2019 (CN) 201910540643.8

(51) Int. Cl. G01P 15/09; H01L 41/113; H01L 41/047; H01R 13/405; H01R 13/504; H01R 24/38

(52) U.S. Cl. CPC G01P 15/0922; H01L 41/1132; H01L 41/0475; H01R 2103/00; H01R 13/504; H01R 24/38; H01R 2201/20; H01R 13/405

(57) ABSTRACT

The disclosure provides a charge output element and a piezoelectric acceleration sensor. The charge output element includes: a base including a supporting member and a connecting member disposed on the supporting member; a flexible member sleeved on the connecting member for bending deformation; a mass block assembly disposed around a circumference of the connecting member, wherein the mass block assembly is coupled to the connecting member by the flexible member and suspended above the supporting member to drive the flexible member to be bent and deformed in an extending direction of the connecting member; and a piezoelectric element attached to a surface of the flexible member away from the supporting member and disposed to move along with movement of the flexible member. Therefore, the sensitivity of the charge output element can be improved while the sensitivity of the charge output element is not susceptible to the strain of the base.

### CROSS-REFERENCE TO RELATED APPLICATION

This application is based on and claims priority to Chinese Patent Application No. 201910540643.8 filed on Jun. 21, 2019, which is incorporated herein by reference in its entirety.

### TECHNICAL FIELD

The disclosure relates to the technical field of acceleration sensor, and in particular to a charge output element and a piezoelectric acceleration sensor.

### BACKGROUND

A piezoelectric acceleration sensor, also known as a piezoelectric accelerometer, belongs to an inertial sensor. By using the piezoelectric effect of certain materials such as quartz crystals, the force applied to the piezoelectric element by the mass block will change when the accelerometer is vibrated. When the measured vibration frequency is much lower than the natural frequency of the accelerometer, the change in force is proportional to the measured acceleration. The standard piezoelectric acceleration sensor is used to calibrate acceleration sensor. Therefore, requirements for the sensitivity of the standard piezoelectric acceleration sensor is more stringent, so the piezoelectric acceleration sensor is required to have higher sensitivity. However, the existing piezoelectric acceleration sensors are generally not sensitive enough to meet the requirements of standard piezoelectric acceleration sensors.

Therefore, there is a need for a charge output element with higher sensitivity to meet the requirements of a standard piezoelectric acceleration sensor.

### SUMMARY

Embodiments of the disclosure provide a charge output element and a piezoelectric acceleration sensor that can improve the sensitivity of the charge output element.

One embodiment of the disclosure provides a charge output element including: a base including a supporting member and a connecting member disposed on the supporting member; a flexible member sleeved on the connecting member for bending deformation; a mass block assembly disposed around a circumference of the connecting member, wherein the mass block assembly is coupled to the connecting member by the flexible member and suspended above the supporting member to drive the flexible member to be bent and deformed in an extending direction of the connecting member; and a piezoelectric element attached to a surface of the flexible member away from the supporting member and disposed to move along with movement of the flexible member.

According to an aspect of the embodiment of the disclosure, the connecting member includes a base portion and a fixing portion which are disposed coaxially and connected to each other, the flexible member is provided with a through hole corresponding to the fixing portion and penetrating the flexible member in the extending direction, and the fixing portion is disposed in the through hole and is connected fixedly to a side wall forming the through hole.

According to an aspect of the embodiment of the disclosure, in a direction perpendicular to the extending direction, the fixing portion has a maximum cross-sectional area smaller than a minimum cross-sectional area of the base portion such that a transition surface is formed between the fixing portion and the base portion, and the flexible member abuts against the transition surface.

According to an aspect of the embodiment of the disclosure, in a direction perpendicular to the extending direction, the flexible member has a cross-sectional area being 11 to 17 times a maximum cross-sectional area of the fixing portion; and/or, in the direction perpendicular to the extending direction, the flexible member has the cross-sectional area being 5.5 to 8.5 times a minimum cross-sectional area of the base portion; and/or in the direction perpendicular to the extending direction, the flexible member has the cross-sectional area being 2.5 to 5.5 times a maximum cross-sectional area of the base portion.

According to an aspect of the embodiment of the disclosure, the flexible member has a uniform thickness in the extending direction.

According to an aspect of the embodiment of the disclosure, the piezoelectric element and the fixing portion are spaced apart in the extending direction.

According to an aspect of the embodiment of the disclosure, an insulating member is provided between the piezoelectric element and the flexible member, and the flexible member has a thickness being 2 to 4 times a distance between two surfaces of the insulating member and the fixing portion that face each other.

According to an aspect of the embodiment of the disclosure, the piezoelectric element is subjected to a polarization treatment in the extending direction, and the piezoelectric element and the mass block assembly are respectively fixed to two opposite sides of the flexible member away from the supporting member and close to the supporting member in a manner of being partially overlapped in the extending direction.

Another embodiment of the disclosure provides a piezoelectric acceleration sensor including: the above mentioned charge output element; and a connector mounted inside the base, wherein the connector is electrically connected to the piezoelectric element to output a signal of the charge output element from the piezoelectric acceleration sensor.

According to an aspect of the embodiment of the disclosure, the connector includes a connector housing; a pin disposed inside the connector housing and coaxially with the connector housing, wherein a first glass layer is provided between the connector housing and the pin, and the connector housing and the pin are fixed by sintering using the first glass layer; and a fixing ring sleeved outside the connector housing and disposed coaxially with the connector housing, wherein a second glass layer is provided between the connector housing and the fixing ring, and the connector housing and the fixing ring are fixed by sintering using the second glass layer.

In the charge output element and the piezoelectric acceleration sensor according to the embodiments of the disclosure, the mass block assembly is disposed around the circumferential of the connecting member, the top of the mass block assembly is connected fixedly to the flexible member, and the flexible member is suspended above the supporting member, such that the mass block assembly applies an inertial force to the flexible member to cause flexible member to be bent and deformed when the mass block assembly subjected to acceleration. Further, the piezoelectric element is disposed on the top of the flexible member, and the lower surface of the piezoelectric element is attached to the upper surface of the flexible member and the lower surface of the piezoelectric element is connected fixedly to the upper surface of the flexible member, so that the bending deformation of the flexible member can be transmitted to the piezoelectric member, and a larger charge output can be generated through the flexural electric effect of the piezoelectric member. Therefore, the sensitivity of the charge output element is further improved while the sensitivity of the charge output component is not susceptible to the strain of the base.

### BRIEF DESCRIPTION OF THE DRAWINGS

Features, advantages, and technical effects of the exemplary embodiments of the disclosure will be described below with reference to the accompanying drawings, wherein:

FIG. 1 shows a schematic perspective view of a piezoelectric acceleration sensor according to an embodiment of the disclosure;

FIG. 2 shows a schematic plan view of the piezoelectric acceleration sensor shown in FIG. 1;

FIG. 3 shows a cross-sectional view taken along the line A-A of the piezoelectric acceleration sensor shown in FIG. 2;

FIG. 4 shows a schematic plan view of the piezoelectric acceleration sensor shown in FIG. 2 with the casing removed;

FIG. 5 shows a schematic structural view of a charge output element according to an embodiment of the disclosure;

FIG. 6 shows a schematic structural view of a base according to an embodiment of the disclosure; and

FIG. 7 shows a schematic structural view of a connector according to an embodiment of the disclosure.

### DESCRIPTION OF REFERENCE SIGNS

| | | | |
|---|---|---|---|
| 1 | charge output element; | 10 | base; |
| 11 | supporting member; | 111 | notch; |
| 112 | recess; | 12 | connecting member; |
| 121 | base portion; | 122 | fixing portion; |
| 123 | transition surface; | 20 | flexible member; |
| 21 | through hole; | 30 | mass block assembly; |
| 31 | mass block; | 40 | piezoelectric element; |
| 50 | insulating member; | 2 | connector; |
| 201 | connector housing; | 202 | pin; |
| 203 | fixing ring; | 204 | first glass layer; |
| 205 | second glass layer; | 206 | insulating layer; |
| 3 | signal line; | 4 | casing; |
| Z | extending direction of the connecting member; | | |
| L | thickness of the flexible member; | | |
| D | distance between two surfaces of the insulating | | |
| | member and the fixing portion that face each other. | | |

In the drawings, the same components are denoted by the same reference signs. The drawings are not drawn to scale.

### DETAILED DESCRIPTION

Features and exemplary embodiments of various aspects of the disclosure are described in detail below. In the following detailed description, numerous specific details are set forth to provide comprehensive understanding of the disclosure. However, it will be apparent to the skilled in the art that the disclosure may be practiced without some of the specific details. The following description of the embodiments is merely to provide a better understanding of the disclosure. In the drawings and the following description, at least some of the known structures and techniques are not shown, to avoid unnecessarily obscuring the disclosure. Further, for clarity, the dimension of some of the structures may be enlarged. Furthermore, features, structures, or characteristics described hereinafter may be combined in any suitable manner in one or more embodiments.

The orientation terms appearing in the following description refer to the directions shown in the drawings, and are not intended to limit the specific structure of the charge output element 1 and the piezoelectric acceleration sensor of the disclosure. In the description of the disclosure, it should also be noted that, unless otherwise explicitly stated and defined, the terms “mount” or “connect” shall be understood broadly, for example, they may be fixed connection or detachable connection or integral connection; alternatively, they may be direct connection or indirect connection. The specific meaning of the above terms in the disclosure may be understood by the skilled in the art based on the specific situation.

The embodiment of the disclosure provides a piezoelectric acceleration sensor, which is capable of improving the sensitivity while simplifying the structure and reducing the processing difficulty, and which is not susceptible to the strain of the base 10.

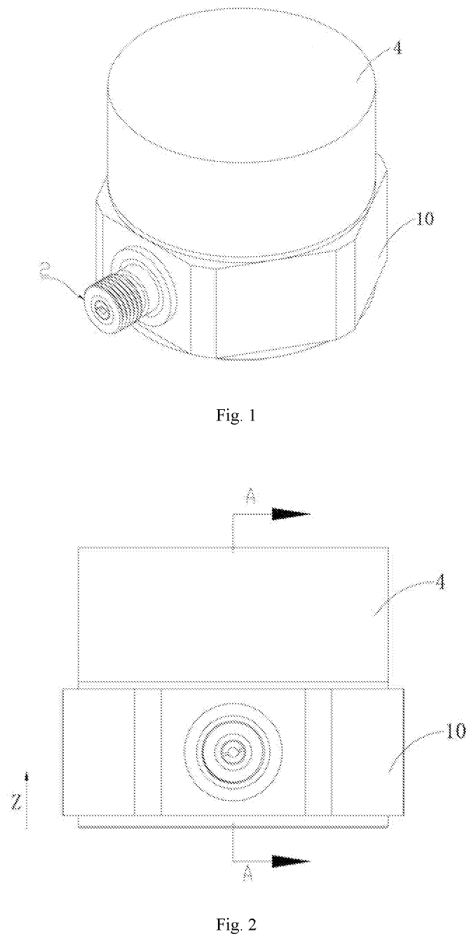

For a better understanding of the disclosure, a piezoelectric acceleration sensor according to an embodiment of the disclosure will be described in detail below with reference to FIGS. 1 to 7.

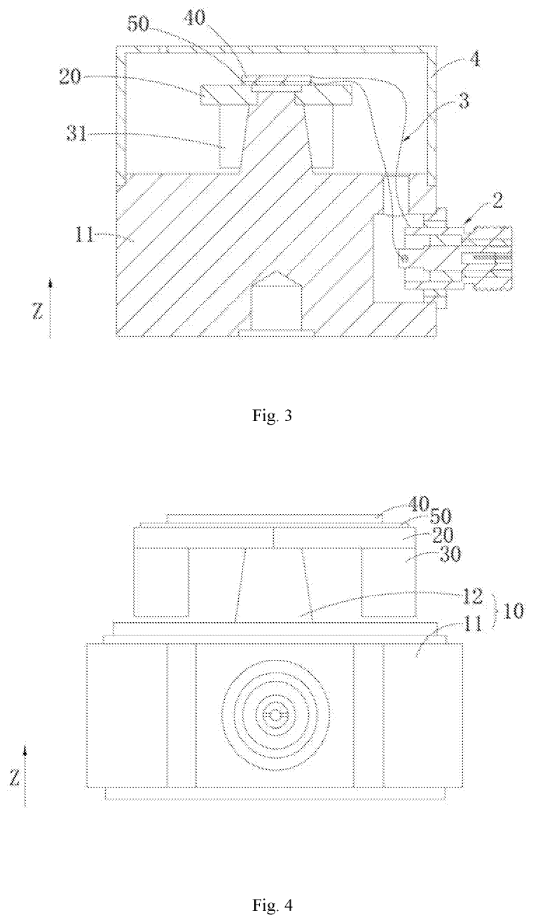

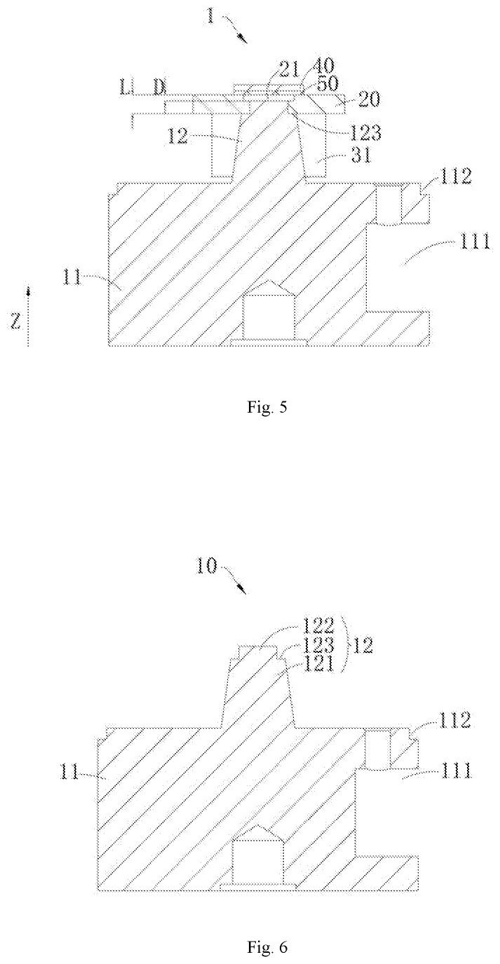

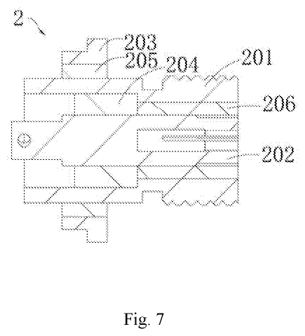

FIG. 1 shows a schematic perspective view of a piezoelectric acceleration sensor according to an embodiment of the disclosure; FIG. 2 shows a schematic plan view of the piezoelectric acceleration sensor shown in FIG. 1; FIG. 3 shows a cross-sectional view taken along the line A-A of the piezoelectric acceleration sensor shown in FIG. 2; FIG. 4 shows a schematic plan view of the piezoelectric acceleration sensor shown in FIG. 2 with the casing 4 removed; FIG. 5 shows a schematic structural view of a charge output element 1 according to an embodiment of the disclosure; FIG. 6 shows a schematic structural view of a base 10 according to an embodiment of the disclosure; and FIG. 7 shows a schematic structural view of a connector 2 according to an embodiment of the disclosure.

Referring to FIGS. 1 to 4, the piezoelectric acceleration sensor according to the embodiment of the disclosure includes a charge output element 1, a connector 2, and a casing 4. The connector 2 and the casing 4 are both connected to the charge output element 1. The charge output element 1 includes a base 10 including a supporting member 11 and a connecting member 12 disposed on the supporting member 11; a flexible member 20 sleeved on the connecting member 12 for bending deformation; and a mass block assembly 30 disposed around the circumference of the connecting member 12, wherein the mass block assembly 30 is coupled to the connecting member 12 by the flexible member 20 and is suspended above the supporting member 11 to drive the flexible member 20 to be bent and deformed in the extending direction Z of the connecting member 12; and a piezoelectric element 40 and an insulating member 50, wherein two surfaces of the insulating member 50 in the extending direction Z are respectively attached to the surface of the flexible member 20 away from the supporting member 11 and the surface of the piezoelectric element 40 close to the supporting member 11, and the piezoelectric element 40 and the insulating member 50 are both disposed to move along with movement of the flexible member 20.

Specifically, the supporting member 11 has a columnar structure as a support for the entire piezoelectric acceleration sensor. A notch 111 matching the connector 2 is provided on the side wall of the supporting member 11 for mounting the connector 2. The connecting member 12 includes a base portion 121 and a fixing portion 122 which are coaxially disposed and connected to each other. The base portion 121 has a frustum structure and is connected to a central portion on the side of the supporting member 11 close to the flexible member 20. In a direction perpendicular to the extending direction Z, the supporting member 11 has a cross-sectional area being 3 to 6 times the maximum cross-sectional area of the base portion 121, so that the stability of the entire base 10 can be improved. In some alternative examples, the supporting member 11 is not limited to the above-described columnar structure, for example, any other structure that can achieve supporting function, such as a frustum structure, a truncated prismatic structure, or a prismatic structure, may be possible. Likewise, the base portion 121 is not limited to the above-described frustum structure, and other structures other than the frustum structure in which in the extending direction Z, the dimension of the end of the base portion 121 adjacent to the flexible member 20 is smaller than the dimension of the end of the base portion 121 away from the flexible member 20 may also be possible. Such structures can minimize the influence of the base 10 on the deformation of the flexible member 20 and the piezoelectric element 40 when an acceleration is applied to the piezoelectric acceleration sensor, and can also ensure the stability of the support of the base 10 to the flexible member 20 and the piezoelectric element 40. Of course, the base portion 121 may be implemented as a columnar structure, a truncated prismatic structure, a prismatic structure or any other structure that satisfies the design requirements.

In some alternative examples, the fixing portion 122 has a columnar structure. The flexible member 20 is provided with a through hole 21 corresponding to the fixing portion 122 and penetrating the flexible member 20 in the extending direction Z, and the fixing portion 122 is disposed in the through hole 21. The outer peripheral surface of the fixing portion 122 and the side wall forming the through hole 21 are fixed by welding. Alternatively, the outer peripheral surface of the fixing portion 122 and the side wall forming the through hole 21 may be fixed by laser welding process, and the welding depth may be optionally from 0.15 to 0.25 mm. In the direction perpendicular to the extending direction Z, the fixing portion 122 has a maximum cross-sectional area being smaller than the minimum cross-sectional area of the base portion 121, such that a transition surface 123 is formed between the fixing portion 122 and the base portion 121. The fixing portion 122 is disposed in the through hole 21 of the flexible member 20 and the flexible member 20 abuts against the transition surface 123. In other words, a shoulder structure on which the flexible member 20 is snapped is formed at the end of the fixing portion 122 away from the flexible member 20 and the end of the base portion 121 adjacent to the flexible member 20. Alternatively, the fixing portion 122 is not limited to the columnar structure. In some alternative examples, the fixing portion 122 may also be implemented as a frustum structure, a truncated prismatic structure, a prismatic structure, or the like. The connection between the fixing portion 122 and the side wall forming the through hole 21 is not limited to welding, and other connection such as gluing may also be possible.

Alternatively, in the direction perpendicular to the extending direction Z, the flexible member 20 has a cross-sectional area being 11 to 17 times the maximum cross-sectional area of the fixing portion 122. In the direction perpendicular to the extending direction Z, the flexible member 20 has a cross-sectional area being 5.5 to 8.5 times the minimum cross-sectional area of the base portion 121. In the direction perpendicular to the extending direction Z, the flexible member 20 has a cross-sectional area being 2.5 to 5.5 times the maximum cross-sectional area of the base portion 121. Alternatively, the distance between the surface on the side of the flexible member 20 close to the supporting member 11 and the upper surface of the supporting member 11 is 11.7 to 15 times the distance between the surface on the side of the mass block assembly 30 close to the supporting member 11 and the upper surface of the supporting member 11. The above structural dimensions can ensure the stability of the support of the base 10 to the flexible member 20, the insulating member 50, the piezoelectric element 40, and the mass block assembly 30, while reducing the influence of the base 10 on the sensitivity of the piezoelectric element 40. It should be noted that, in the direction perpendicular to the extending direction Z, the numerical relationship among the cross-sectional area of the flexible member 20, the cross-sectional area of the fixing portion 122, and the cross-sectional area of the base portion 121 is not limited to the above specific numerical range, and any other dimension that satisfies design and use requirements may be possible.

A recess 112 that is sized to match the casing 4 is provided at the outer edge of the end of the supporting member 11 close to the flexible member 20, and the recess 112 is used to mount the casing 4. The casing 4 of the piezoelectric acceleration sensor includes a receiving cavity and an opening communicating with the receiving cavity. The opening of the casing 4 faces the supporting member 11 and is fixed to the recess 112 disposed at the outer edge of the supporting member 11 by welding, so as to house the piezoelectric element 40, the flexible member 20 and the mass block 31 within the casing 4. Alternatively, the casing 4 and the recess 112 disposed at the outer edge of the supporting member 11 is fixed by laser welding process with a welding depth of 0.15-0.25 mm. The connection between the casing 4 and the supporting member 11 is not limited to the above-described welding, and the connection such as gluing or riveting may be possible.

The flexible member 20 may be a structural member that can be deformed when subjected to a force and cannot be restored to its original state after the force is withdrawn, and may employ an alloy material such as stainless steel, titanium alloy, or the like. The flexible member 20 has a plate-like structure having a certain thickness in the extending direction Z. Specifically, the flexible member 20 has a plate-like structure having a regular hexagonal cross section, in which the through hole 21 matching the fixing portion 122 of the connecting member 12 is provided in the central portion of the flexible member 20. When the piezoelectric acceleration sensor is assembled, the flexible member 20 is attached to the connecting member 12 via the through hole 21. Two mounting holes for mounting the mass blocks 31 are symmetrically disposed on the flexible member 20 at both sides of the through holes 21. Accordingly, the mass block assembly 30 includes two mass blocks 31, wherein the end of each mass block 31 adjacent to the flexible member 20 is provided with a mounting post matching the mounting hole in the flexible member 20. The outer peripheral surface of the mounting post and the side wall forming the mounting hole are fixed by welding, and thereby the fixing of the mass block 31 and the flexible member 20 is achieved. Alternatively, the mounting post of the mass block and the side wall forming the mounting hole may be fixed by the laser welding process with the welding depth of 0.15-0.25 mm. When an acceleration is applied to the mass block 31, the flexible member 20 may be bent and deformed in the extending direction Z. In some alternative examples, the flexible member 20 has a uniform thickness in extending direction Z, and when the thickness L of the flexible member 20 is relatively small, the flexible member 20 has a sheet-like structure. The insulating member 50 and the fixing portion 122 are spaced apart in the extending direction Z, and the thickness L of the flexible member 20 is 2 to 4 times the distance D between the two surfaces of the insulating member 50 and the fixing portion 122 that face each other. Of course, this is only an optional times range, and the distance D between the two surfaces of the insulating member 50 and the fixing portion 122 that face each other and the thickness L of the flexible member 20 may also be designed in other times, as long as the actual design requirements are met. However, in the specific design, it should be noted that, if the distance D between the two surfaces of the insulating member 50 and the fixing portion 122 that face each other is too small, the piezoelectric sensor is susceptible to the strain of the base 10, resulting in a larger strain sensitivity of base 10; if the distance D between the two surfaces of the insulating member 50 and the fixing portion 122 that face each other is too large, the connection between the flexible member 20 and the connecting member 12 is liable to be weak.

Alternatively, the mass block assembly 30 includes two mass blocks 31, each mass block 31 including a rectangular block and a mounting post disposed in the central portion of the rectangular block. When the mass block 31 is fixed to the flexible member 20 by the mounting post, the side wall on the side of the rectangular block away from the connecting member 12 is flush with the outer wall of the flexible member 20. Such structural design can ensure that the bending deformation of the entire flexible member 20 is relatively uniform when an acceleration is applied to the mass block 31. Of course, in some alternative examples, the mass block 31 may be offset from the position of the present embodiment away from or toward the connecting member 12, as long as the requirements are met. In some alternative examples, the mass block 31 may also be an annular structure that is sleeved outside the connecting member 12, and alternatively, a gap may exist between the two annular faces of the annular structure and the connecting member 12 that face each other. The mass block assembly 30 may also include two or more mass blocks 31 that are uniformly disposed around the circumference of the connecting member 12.

Alternatively, the piezoelectric element 40 includes one or two or more layers of piezoelectric crystals. The piezoelectric crystal has two surfaces disposed opposite to each other in the extending direction Z, and both surfaces are plated with a gold plating layer. The two or more layers of piezoelectric crystals are stacked in the extending direction Z and connected in parallel with each other, and the two surfaces adjacent to each other of the two adjacent piezoelectric crystals have the same polarity. Alternatively, the gold plating layer has a thickness of 1 μm, or the gold plating layer may has a thickness less than 1 μm, as long as the actual design requirements are met. The material of the piezoelectric element 40 is not limited to the type of the following materials: quartz single crystal, lead zirconate titanate piezoelectric ceramic, bismuth layered ceramic, lithium niobate, or the like. Of course, any other material that satisfies design requirements may be possible.

The insulating member 50 is disposed between the piezoelectric element 40 and the flexible member 20. Alternatively, the insulating member 50 has a sheet-like structure having a first surface and a second surface disposed opposite to each other. The first surface is fixed to the surface on the side of the piezoelectric element 40 facing the insulating member 50 by adhering using the epoxy resin, and the second surface is fixed to the surface on the side of the flexible member 20 facing the insulating member 50 by adhering using the epoxy resin, which is convenient to install and convenient for later disassembly and repair. In some alternative examples, the piezoelectric element 40 and the insulating member 50 may be fixed using other adhesives, and may also be fixed by, for example, riveting, screwing, or the like.

The embodiment of the disclosure further provides a piezoelectric acceleration sensor, wherein the connector 2 is disposed in the notch 111 of the base 10, and the fixing ring 203 of the connector 2 is fixed to the base 10 by welding, optionally by a laser welding process, with a welding depth of 0.15-0.25 mm. The connector 2 is electrically connected to the piezoelectric element 40 through a signal line 3. The connector 2 includes a connector housing 201, a pin 202, and a fixing ring 203. The pin 202 is disposed inside the connector housing 201, a first glass layer 204 is provided between the connector housing 201 and the pin 202, and the connector housing 201 and the pin 202 are fixed by sintering using the first glass layer 204. The fixing ring 203 is sleeved outside the connector housing 201, and a second glass layer 205 is provided between the connector housing 201 and the fixing ring 203, and the connector housing 201 and the retaining ring 203 are fixed by sintering using the second glass layer 205. An insulating layer 206 is provided between the connector housing 201 and the pin 202 at one end of the first glass layer 204. The insulating layer 206 has inner and outer annular surfaces that are disposed opposite, and the inner annular surface is fixed to the outer wall of the pin 202, and the outer annular surface is fixed to the inner wall of the connector housing 201. In the present embodiment, the connector 2 is a single-core connector 2, and the connector 2 is designed as a double-glazed sintered structure to isolate the signal from the casing. As compared to a single-glazed structure, the connector 2 can effectively solve the problem that the connector 2 is susceptible to external noise and the like, especially at low frequencies. Of course, in some alternative examples, the connector 2 may also have a single-glazed structure having only the first glass layer 204 or the second glass layer 205, except that connector 2 having the single-glazed structure has a poor anti-interference ability compared to the double-glazed sintered structure.

The embodiment of the disclosure further provides the charge output element 1, which includes: the base 10 including the supporting member 11 and the connecting member 12 disposed on the supporting member 11; the flexible member 20 sleeved on the connecting member 12 for bending deformation; the mass block assembly 30 disposed around the circumference of the connecting member 12, wherein the mass block assembly 30 is coupled to the connecting member 12 by the flexible member 20 and suspended above the supporting member 11 to drive the flexible member 20 to be bent and deformed in the extending direction Z of the connecting member 12; and the piezoelectric element 40 and the insulating member 50, wherein the two surfaces of the insulating member 50 in the extending direction Z are respectively attached to the surface of the flexible member 20 away from the supporting member 11 and the surface of the piezoelectric element 40 close to the supporting member 11, and the piezoelectric element 40 and the insulating member 50 are both disposed to move along with movement of the flexible member 20. The above charge output element utilizes the mass block assembly 30 to generate an inertial force on the flexible member 20 when subjected to an acceleration, drives the flexible member 20 to be bent and deformed, and transmits the strain to the piezoelectric element 40, and generates a larger charge output by using the flexural electric effect of the piezoelectric element 40, thus improving the sensitivity of the piezoelectric acceleration sensor having the charge output element 1.

Although the disclosure has been described with reference to the preferred embodiments, various modifications may be made thereto and the components may be replaced with equivalents without departing from the scope of the application. In particular, the technical features mentioned in the various embodiments can be combined in any manner as long as there is no structural conflict. The disclosure is not limited to the specific embodiments disclosed herein, but includes all technical solutions falling within the scope of the claims.

What is claimed is:

1. A charge output element, comprising:
a base comprising a supporting member and a connecting member disposed on the supporting member;
a flexible member sleeved on the connecting member for bending deformation;
a mass block assembly disposed around a circumference of the connecting member, wherein the mass block assembly is coupled to the connecting member by the flexible member and suspended above the supporting member to drive the bending deformation of the flexible member to be bent and deformed in an extending direction of the connecting member; and
a piezoelectric element attached to a surface of the flexible member away from the supporting member and disposed to move along with movement of the flexible member.

2. The charge output element according to claim 1, wherein the connecting member comprises a base portion and a fixing portion which are disposed coaxially and connected to each other, the flexible member is provided with a through hole corresponding to the fixing portion and penetrating the flexible member in the extending direction, and the fixing portion is disposed in the through hole and is connected fixedly to a side wall forming the through hole.

3. The charge output element according to claim 2, wherein in a direction perpendicular to the extending direction, the fixing portion has a maximum cross-sectional area smaller than a minimum cross-sectional area of the base portion such that a transition surface is formed between the fixing portion and the base portion, and the flexible member abuts against the transition surface.

4. The charge output element according to claim 2, wherein in a direction perpendicular to the extending direction, the flexible member has a cross-sectional area being 11 to 17 times a maximum cross-sectional area of the fixing portion; and/or,
in the direction perpendicular to the extending direction, the flexible member has the cross-sectional area being 5.5 to 8.5 times a minimum cross-sectional area of the base portion;
and/or in the direction perpendicular to the extending direction, the flexible member has the cross-sectional area being 2.5 to 5.5 times a maximum cross-sectional area of the base portion.

5. The charge output element according to claim 2, wherein the flexible member has a uniform thickness in the extending direction.

6. The charge output element according to claim 2, wherein the piezoelectric element and the fixing portion are spaced apart in the extending direction.

7. The charge output element according to claim 5, wherein an insulating member is provided between the piezoelectric element and the flexible member, and the flexible member has a thickness being 2 to 4 times a distance between two surfaces of the insulating member and the fixing portion that face each other.

8. The charge output element according to claim 1, wherein the piezoelectric element is subjected to polarization treatment in the extending direction, and the piezoelectric element and the mass block assembly are respectively fixed to two opposite sides of the flexible member away from the supporting member and close to the supporting member in a manner of being partially overlapped in the extending direction.

9. A piezoelectric acceleration sensor, comprising:
the charge output element according to claim 1; and
a connector mounted inside the base, wherein the connector is electrically connected to the piezoelectric element to output a signal of the charge output element from the piezoelectric acceleration sensor.

10. The piezoelectric acceleration sensor according to claim 9, wherein the connector comprises:
a connector housing;
a pin disposed inside the connector housing and coaxially with the connector housing, wherein a first glass layer is provided between the connector housing and the pin, and the connector housing and the pin are fixed by sintering using the first glass layer; and
a fixing ring sleeved outside the connector housing and disposed coaxially with the connector housing, wherein a second glass layer is provided between the connector housing and the fixing ring, and the connector housing and the fixing ring are fixed by sintering using the second glass layer.
